(19) United States
(12) Patent Application Publication
(10) Pub. No.: US 2026/0328814 A1
(43) Pub. Date: Oct. 22, 2026

(54) Connector-less apparatus for electrical safety devices that ensures low-cost, error-free dual line-voltage sensing terminations that install directly onto various-sized current-carrying conductors

(71) Applicant: Grace Technologies, Inc., Davenport, IA (US)

(72) Inventors: Philip Brown Allen, Davenport, IA (US); Aaron E. Tuttle, McCausland, IA (US)

(73) Assignee: Grace Technologies, Inc., Davenport, IA (US)

(21) Appl. No.: 19/652,409

(22) Filed: Apr. 20, 2026

Related U.S. Application Data
(60) Provisional application No. 63/868,944, filed on Aug. 22, 2025.
(60) Provisional application No. 63/791,928, filed on Apr. 21, 2025.

(51) Int. Cl. G01R 15/14

(52) U.S. Cl. CPC G01R 15/144

(57) ABSTRACT

A connector-less apparatus to sense voltage for electrical safety devices includes a first termination for a first voltage sense lead wire and a second termination for a second voltage sense lead wire. The apparatus includes an opening for receiving a source conductor. The apparatus is configured such that the first voltage sense lead wire contacts the source conductor at a first position along the source conductor and the second voltage sense lead wire contacts the source conductor at a second position along the source conductor, the first position spaced apart from the second position such that current flows along the source conductor between the first voltage sense lead and the second voltage sense lead when electrical energy is present on the source conductor.

### RELATED APPLICATION

This application claims priority to U.S. Provisional Patent Application No. 63/791,928, filed Apr. 21, 2025 and U.S. Provisional Patent Application No. 63/868,944, filed Aug. 22, 2025, both of which are hereby incorporated by reference in their entireties.

### FIELD OF THE INVENTION

The present disclosure relates to electrical safety devices. More particularly, but not exclusively, the present disclosure relates to a connector-less apparatus for electrical safety devices that ensures low-cost, error-free dual line-voltage low current sensing terminations that installs and adapt directly onto various-sized current-carrying conductors without adding additional connector components or failure points. This invention installs onto source conductors without disrupting or loosening the existing power terminations. Electrical safety depends on highly reliable voltage-sensing connections to the source voltage. Reliably sensing a normal operating voltage level translates into reliably verifying zero voltage once the main isolation switch is open.

### BACKGROUND

Although the background of the present disclosure is discussed primarily in the context of Absence of Voltage Test units (AVTs) it is to be understood that the present disclosure has a wider range of applicability as will be discussed throughout. Therefore, the present disclosure is not to be limited to use with AVTs but may be used with other types of electrical safety and power monitoring devices.

In 2018, Absence of Voltage Test units (AVTs) were recognized by NFPA 70E and UL as a new safety permanently installed device to ensure that a zero electrical energy state exists for electrical and mechanical lockout/tagout (LOTO). These units provide automated “push-button” verification that all electrical conductors and circuit parts are de-energized before maintenance or servicing. After the main isolator is opened, the AVT uses stored energy to perform two tests that verify that a zero-voltage condition exists. A voltage test verifies that the voltage between the phase conductor(s) and ground does not exceed 3 volts RMS, and a continuity test verifies that the AVT’s voltage sensor lead-wire(s) (VSL) are securely connected to the current-carrying source conductor(s). The AVT circuitry for the continuity test requires two 14AWG voltage sense leads (VSLs) per phase (nomenclature: L1-A/L1-B, L2-A/L2-B, L3-A/L3-B, GRD-A/GRD-B)-eight wires in total. The AVT confirms continuity by injecting a test current into the ‘A’ lead wire, which then flows through the source conductor into the ‘B’ lead wire, where the test current loop is sensed by the AVT circuitry. Without verifying with a continuity test that both VSLs are securely terminated to the source and ground conductor(s), the AVT could indicate a zero-voltage condition when voltage is still present, resulting in severe shock injury or death.

Despite the advantages of electrical safety devices such as AVTs, safety can still be compromised if installation is not completed correctly or if continuity of both VSLs is not verified to both source and ground conductors. Typical installations are time-consuming, impractical, and error-prone, as isolators typically accept only one source conductor and have few options for terminating other low-current sensing leads. Additionally, field AVT installations on higher current applications often do not allow installers to loosen a previously field-approved torqued lug connection(s) on the main current-carrying conductor(s), creating further installation challenges. Installer may crimp a male Sta-Kon® (a brand name for a solderless crimp terminal which may sometimes also be called a wire terminal, lug, or connector) at the end of the leads and loosen the current carrying conductors and slip this into the same lug opening. However, this workaround is problematic because it can compromise the mechanical integrity and torque specifications of the original high-current connection, potentially leading to increased contact resistance, overheating, or loosening over time. Moreover, installed larger conductors have been torqued and are verified at startup, so to loosen the connection point is not an option.

Thus, despite the advantages of electrical safety devices such as AVTs, safety can still be compromised if installation is not completed correctly or if continuity of both VSLs is not verified to both source and the ground conductors.

### SUMMARY

Therefore, it is a primary object, feature, or advantage to improve over the state of the art.

It is a further object, feature, or advantage to increase safety associated with use of electrical safety device including AVTs, Permanent Electrical Safety Devices (PESD), on isolators such as safety switches, rotary disconnects, fusible/non-fusible disconnects, circuit breakers, and other types of electrical power isolation devices.

It is another object, feature, or advantage to provide a connector-less apparatus that eliminates installation errors by ensuring proper connection and spacing between voltage sense lead terminations on source conductors.

It is another object, feature, or advantage to provide a connector-less apparatus that accommodates a range of conductor sizes without necessarily requiring additional hardware, thereby accommodating installations in which the branch-circuit load is not known in advance and a single apparatus must be compatible with the full range of conductor gauges permitted by the upstream protective device (for example, a 30A isolator accepting conductor sizes from #14AWG to #8AWG), so as to accommodate and simplify field installation requirements and challenges.

It is another object, feature, or advantage to provide a connector-less apparatus that reduces installation time and cost while ensuring correct voltage sense lead connections.

It is another object, feature, or advantage to provide an overmolded design that prevents inadvertent swapping of voltage sense leads between phase.

It is another object, feature, or advantage to provide a design that utilizes existing conductor real estate without interfering field wiring and requiring a larger electrical panel.

It is another object, feature, or advantage to provide multiple reliable electrical contact paths between voltage sense leads and source conductors.

It is another object, feature, or advantage to provide improved safety in electrical lockout/tagout procedures by ensuring proper continuity verification in absence of voltage testing.

It is another object, feature, or advantage to provide a connector-less apparatus that allows voltage sense leads to be terminated to a source conductor without loosening previously torqued lug connections on the source conductor.

It is another object, feature, or advantage to provide a field-installable connector-less apparatus that can be assembled around voltage sense leads in the field without requiring an overmolded termination.

It is another object, feature, or advantage to provide a connector-less apparatus configured to resist rotation relative to a source conductor.

It is another object, feature, or advantage to provide a connector-less apparatus that gauges stripped-wire length of a voltage sense lead to promote consistent, reliable mechanical and electrical contact with a source conductor.

It is another object, feature, or advantage to provide a connector-less apparatus suitable for use with single-phase, two-phase, three-phase, and direct-current power systems.

A further object, feature, or advantage is to provide a connector which is finger safe in that there is no finger access to voltage.

It is another object, feature, or advantage to provide a connector-less apparatus suitable for use with a range of electrical safety and power monitoring devices, including absence of voltage testers, permanent electrical safety devices, voltage presence indicators, and other power monitoring or test equipment. Furthermore, these devices receive field wiring or various sizes, so the connector-less apparatus needs to accommodate a range of wire sizes, since the field wiring that may be determined by the field electrician.

One or more if these and/or other objects, features, or advantages will be apparent from the description that follows. No single embodiment need include or provide each and every object, feature, or advantage. Different embodiments may have different objects, features, or advantages.

According to one aspect, a connector-less apparatus for electrical safety devices includes a first termination for a first voltage sense lead wire and a second termination for a second voltage sense lead wire. The apparatus includes an opening for receiving a source conductor. The apparatus is configured such that the first voltage sense lead wire contacts the source conductor at a first position along the source conductor and the second voltage sense lead wire contacts the source conductor at a second position along the source conductor. The first position is spaced apart from the second position such that test current flows along the source conductor between the first voltage sense lead and the second voltage sense lead when electrical energy is present on the source conductor.

The connector-less apparatus may include a plurality of connector-less apparatuses for electrical safety devices with a first connector-less apparatus for a L1 source conductor, a second connector-less apparatus for a L2 source conductor, and a third connector-less apparatus for a L3 source conductor. The connector-less apparatus may further include an isolation device configured to disconnect the source conductors from an upstream power source, the isolation device comprising one of a safety switch, a rotary disconnect, a fusible disconnect, a non-fusible disconnect, and a circuit breaker. The connector-less apparatus may include a lug adapter body. The connector-less apparatus may include a first termination that is a first lead crimp termination and a second termination that is a second lead crimp termination. The connector-less apparatus may include a first termination that is a first screw termination and a second termination that is a second screw termination. The connector-less apparatus may include a ring adapter body. The first termination may be a first lead screw termination and the second termination may be a second lead screw termination. The connector-less apparatus may include an opening that is between a first assembly and a base assembly.

The connector-less apparatus may include a first assembly that is configured to receive the first voltage sense lead and the second voltage sense lead. The connector-less apparatus may include a first assembly that provides an overmolded termination end for receiving both the first voltage sense lead and the second voltage sense lead configured such that in an operative position both the first voltage sense lead and the second voltage sense lead electrically connect to the source.

According to another aspect, a connector-less apparatus for electrical safety devices includes an L1 source conductor sub-assembly, an L2 source conductor sub-assembly, and an L3 source conductor sub-assembly. The L1 source conductor sub-assembly includes a first termination for a first voltage sense lead wire, a second termination for a second voltage sense lead wire, and an opening for receiving an L1 source conductor. The apparatus is configured such that the first voltage sense lead wire contacts the L1 source conductor at a first position along the L1 source conductor and the second voltage sense lead wire contacts the L1 source conductor at a second position along the L1 source conductor. The first position is spaced apart from the second position such that current flows along the L1 source conductor between the first voltage sense lead and the second voltage sense lead when electrical energy is present on the L1 source conductor. The L2 source conductor sub-assembly and L3 source conductor sub-assembly have similar configurations for their respective source conductors.

The connector-less apparatus may be associated with an isolation device configured to disconnect the L1, L2, and L3 source conductors from an upstream power source, the isolation device comprising one of a safety switch, a rotary disconnect, a fusible disconnect, a non-fusible disconnect, and a circuit breaker. The connector-less apparatus may include an L1 source conductor sub-assembly associated with a first adaptor plate, an L2 source conductor sub-assembly associated with a second adaptor plate, and an L3 source conductor sub-assembly associated with a third adaptor plate. The connector-less apparatus may include an L1 source conductor sub-assembly that is a first lug adapter assembly, an L2 source conductor sub-assembly that is a second lug adapter assembly, and an L3 source conductor sub-assembly that is a third lug adapter assembly. The connector-less apparatus may include an L1 source conductor sub-assembly that is a first ring collar assembly, an L2 source conductor sub-assembly that is a second ring collar assembly, and an L3 source conductor sub-assembly that is a third ring collar assembly.

According to yet another aspect, a connector-less apparatus for electrical safety devices includes a first assembly for receiving a first voltage sense lead and a second voltage sense lead, both the first voltage sense lead and the second voltage sense lead associated with absence of voltage testing of a first source conductor. The first assembly provides an overmolded termination end for receiving both the first voltage sense lead and the second voltage sense lead configured such that in an operative position both the first voltage sense lead and the second voltage sense lead electrically connect to the source conductor at spaced apart locations along the first source conductor. The apparatus includes a first mounting base which in an operative position secures to the first assembly with the first source conductor positioned therebetween. The apparatus includes a first screw and a second screw for securing the first assembly to the first mounting base. The apparatus includes an adapter plate having a first aperture for the first screw and a spaced apart second aperture for the second screw.

The connector-less apparatus may include a second assembly for receiving a third voltage sense lead and a fourth voltage sense lead, both the third voltage sense lead and the fourth voltage sense lead associated with absence of voltage testing of a second source conductor. The second assembly may provide an overmolded termination end for receiving both the third voltage sense lead and the fourth voltage sense lead configured such that in an operative position both the third voltage sense lead and the fourth voltage sense lead electrically connect to the second source conductor at spaced apart locations along the second source conductor. The apparatus may include a second mounting base which in an operative position secures to the second assembly with the second source conductor positioned therebetween. The apparatus may include a third screw and a fourth screw for securing the second assembly to the second mounting base.

The connector-less apparatus may include a first assembly with a surface configured to contact the first source conductor, the surface having a contoured shape that centers the first source conductor regardless of conductor gauge size. The connector-less apparatus may include a first voltage sense lead and a second voltage sense lead each having a mashed end portion configured to provide multiple contact points with the first source conductor, thereby creating redundant electrical paths for improved reliability during continuity testing. The connector-less apparatus may include a first assembly and a first mounting base that are configured to accommodate source conductors spanning the full range of gauges compatible with a given upstream protective device such as #14AWG to #8AWG for a 30A isolator, #14AWG to #4AWG for higher-current applications, or #8 to 2/0 for feeder-scale applications, without requiring additional hardware or modification, so that a single apparatus may be specified before the ultimate branch-circuit load is known.

According to yet another aspect, a connector-less apparatus for electrical safety devices includes a two-part assembly configured to receive a first voltage sense lead and a second voltage sense lead, the two-part assembly configured to hold the first voltage sense lead and the second voltage sense lead such that a stripped end of the first voltage sense lead and a stripped end of the second voltage sense lead protrude from the two-part assembly. The apparatus further includes a base assembly configured to hold a first source conductor. The two-part assembly is configured to be inserted into and secured to the base assembly such that, in an operative position, the stripped end of the first voltage sense lead meshes against the first source conductor at a first position along the first source conductor and the stripped end of the second voltage sense lead meshes against the first source conductor at a second position along the first source conductor spaced apart from the first position, such that current flows along the first source conductor between the first voltage sense lead and the second voltage sense lead when electrical energy is present on the first source conductor.

The connector-less apparatus may include a two-part assembly having a first clamp member and a second clamp member configured to mate together and together defining a first wire channel for the first voltage sense lead and a second wire channel for the second voltage sense lead. The connector-less apparatus may include a first fastener passing through the first clamp member and into the base assembly and a second fastener passing through the second clamp member and into the base assembly to secure the two-part assembly to the base assembly. The connector-less apparatus may include a third fastener securing the first clamp member to the second clamp member. The connector-less apparatus may include an anti-rotation structure positioned on the base assembly and configured to engage the first source conductor. The connector-less apparatus may include at least one surface defining a portion of an opening having a contoured shape configured to center a source conductor across a range of conductor gauge sizes. The connector-less apparatus may include a sacrificial position tab configured to gauge a stripped length of a voltage sense lead and configured to be removed prior to the apparatus reaching an operative position.

### BRIEF DESCRIPTION OF THE DRAWINGS

FIG. 1 illustrates one example of a connector-less conductor mounted error-free dual voltage sense lead termination apparatus with a rotary disconnect switch.

FIG. 2 illustrates a detailed view of a conductor position assembly.

FIG. 3A illustrates the conductor position assembly accommodating a larger gauge conductor.

FIG. 3B illustrates the conductor position assembly accommodating a smaller gauge conductor.

FIG. 4 illustrates another view of the conductor position assembly.

FIG. 5 illustrates an in-line male-female lug with dual crimp and/or screw terminations where the source conductors are terminated to a rotary disconnect switch.

FIG. 6 illustrates a detailed view of the lug shown in FIG. 5.

FIG. 7 illustrates the male-female lug adapter wired to a rotary disconnect switch.

FIG. 8 illustrates a ring collar adapter with two voltage sensor lead screw terminations.

FIG. 9 illustrates the importance of spaced apart terminations of voltage sense leads to the source conductor in the context of an absence of voltage tester.

FIG. 10 illustrates the mandatory continuity path with two source connections required for AVT test functionality.

FIGS. 11A and 11B illustrate pictorial representations the connector-less apparatus similar to that shown in FIG. 1. To better show the connector-less apparatus mounted to the source conductor, the voltage sensor lead wires were left out of FIG. 11B.

FIG. 12 illustrates another example of the conductor position assembly.

FIG. 13 illustrates another view of the conductor position assembly.

FIG. 14 illustrates another view of the conductor position assembly.

FIG. 15 illustrates another view of the conductor position assembly.

FIG. 16 illustrates another view of the conductor position assembly.

FIG. 17 illustrates another view of the conductor position assembly.

FIG. 18 illustrates another view of the conductor position assembly.

FIG. 19 illustrates one embodiment of a disconnect which may mount in an enclosure assembly with a connector-less connector mounted in a stationary position.

FIG. 20 illustrates another view of a three-in-one device shown in FIG. 19.

FIG. 21 illustrates a sacrificial stripped conductor position mechanism.

FIG. 22 illustrates another embodiment of a sacrificial stripped-conductor position mechanism.

FIG. 23 illustrates a single-conductor connector-less connector configured to resist rotation in this embodiment using cleat or spike positioned to resist rotation.

### DETAILED DESCRIPTION

The present disclosure generally provides a mechanical design that ensures that each voltage sense lead (VSL) connects to a source conductor in two distinct locations which are spaced apart from each other thereby eliminating the possibility of a wiring error by the installer, where both VSLs are terminated at the same location on the source conductor. In addition, in some embodiments, the two VSLs for each phase may be overmolded together to ensure that a phase VSL is not inadvertently swapped between phases—L1-A gets swapped with L2-B, etc. The source conductor provides ample unused real estate for terminating the eight #14AWG VSLs without adding additional hardware (terminal blocks, etc.) and will also not interfere with the field wiring. This apparatus is also designed to accommodate a range of load wire sizes, with the ability to adapt to final conductor sizing variations, which simplifies installation. This apparatus deploys a 'connector-less' design to create a current path between the source conductor and the VSL by mashing, pushing, and holding the #14AWG stranded wire ends onto the source conductor. This approach potentially provides many contact paths because #14AWG stranded wire has 41 individual wire strands. Because the VSL circuit limits the current to the AVT to less than 2mA, the apparatus will not be subjected to overcurrent damage.

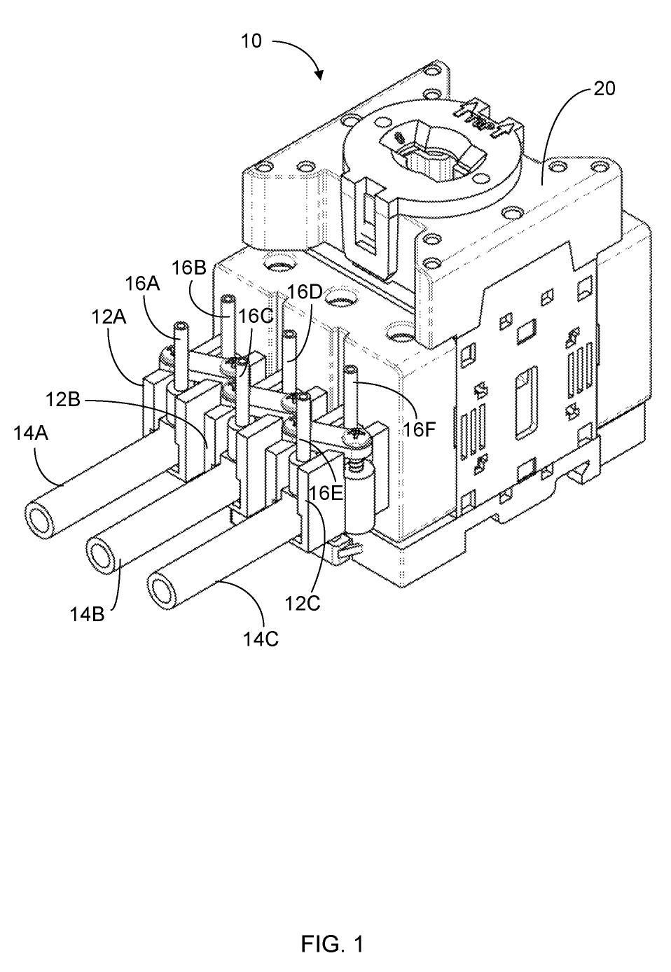

FIG. 1 illustrates one example of a connector-less conductor mounted error-free dual voltage sense lead termination apparatus 10 with a rotary disconnect switch 20. As shown in FIG. 1, there are three conductor position assemblies 12A, 12B, 12C each associated with a corresponding conductor 14A, 14B, 14C. Each of the conductors 14A, 14B, 14C may be a phase conductor within a 3 phase power conductor with L1, L2, L3 phases. For purposes here, GRD is not shown but ground connectors may be included in any number of ways as would be apparent to one skilled in the art.

Each of the conductor position assemblies 12A, 12B, 12C connects two separate voltage sense leads with conductor position assembly 12A having voltage sense leads 16A, 16B, conductor position assembly 12B having voltage sense leads 16C, 16D, and conductor position assembly 12C having voltage sense leads 16E, 16F.

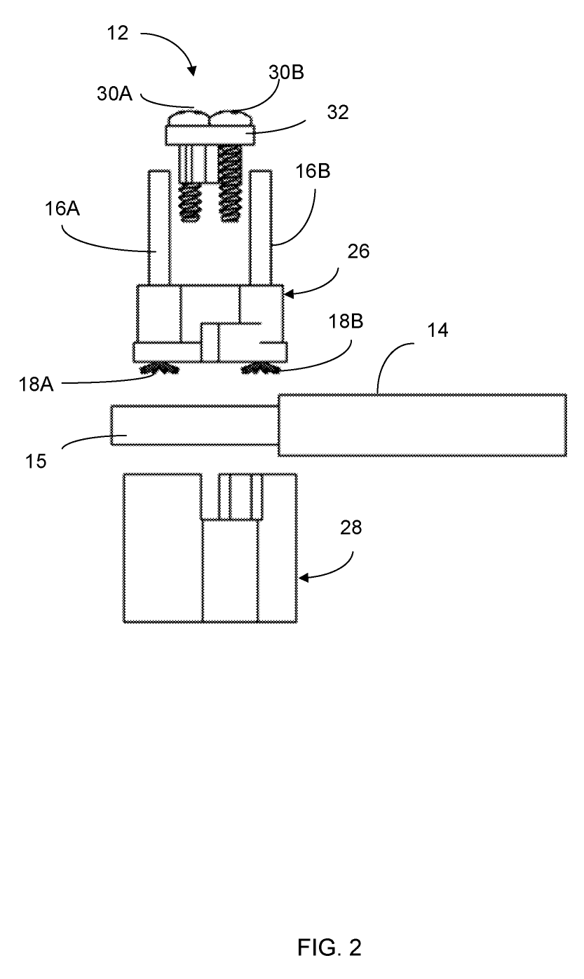

FIG. 2 illustrates one example of a conductor position assembly 12 in more detail. The purpose of the conductor position assembly 12 is to hold the stripped end 15 of the conductor 14 and mechanically and electrically connect each of the voltage sense leads 16A, 16B to the conductor 14 at spaced apart positions along the conductor. Having two separate contact points with space between is critical to certain continuity check operations as will be discussed in more detail. As shown in FIG. 2, the voltage sense leads 16A, 16B each have mashed ends 18A, 18B for electrically contacting the stripped end 15 of the conductor 14.

The conductor position assembly 12 has a termination assembly 26 and a mounting base 28 or base assembly. The termination assembly 26 and mounting base 28 are positioned on opposite ends of the conductor 14. The termination assembly 26 may be overmolded with rubber-like material or other suitable insulative material which also have some give. The termination assembly 26 and the mounting base may then clamp together to secure the source conductor 14 in place. A clamp member 32 may include a first aperture and a second aperture in which screws 30A, 30B are inserted and then tightened into the base assembly 28.

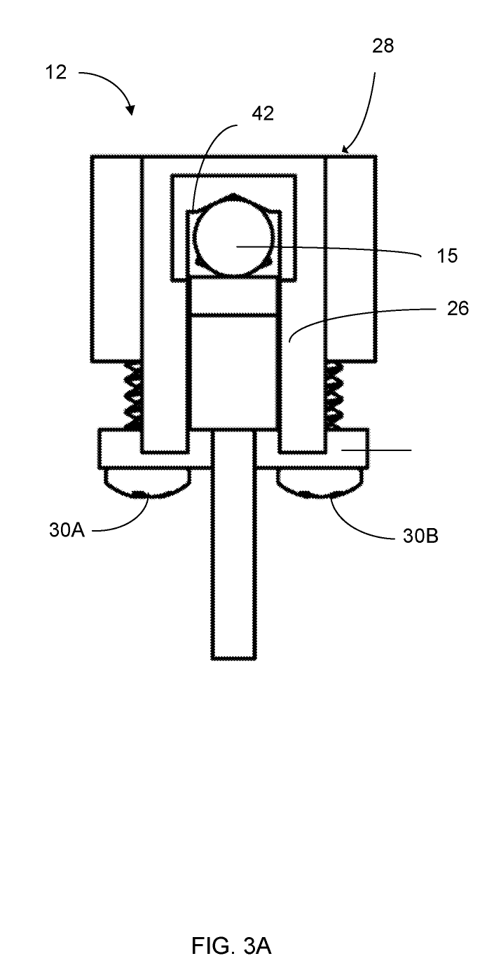

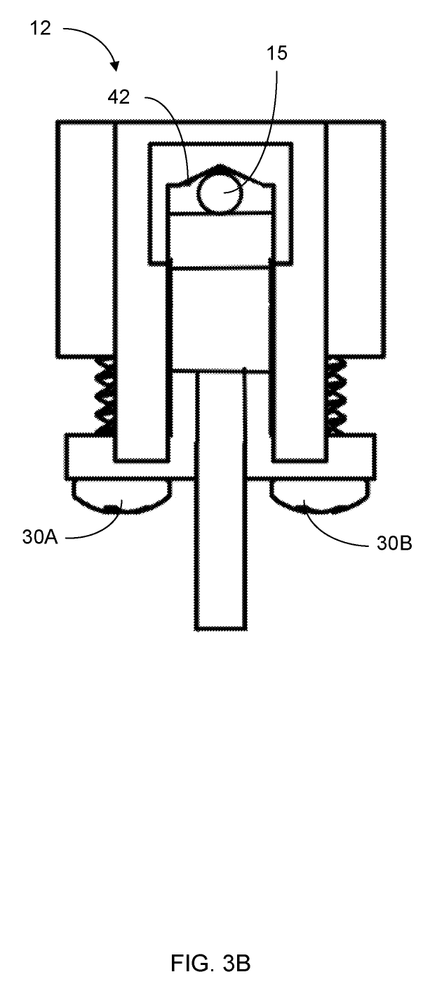

FIG. 3A further illustrates the conductor position assembly 12 with the stripped conductor 15 being of a larger gauge. The stripped conductor 15 fits against a surface 42 of the termination assembly 26. The surface 42 is shaped to better secure the stripped conductor 15 such as by sloping towards the center to provide a predictable and more secure fit. In FIG. 3A, the screws 30A, 30B are tightened with the termination assembly firmly secured to the base assembly 28 and the source conductor firmly held in place so that the voltage sense lead lines are in contact with the source conductor at spaced apart locations.

FIG. 3B further illustrates the conductor position assembly 12 with the conductor 15 being of a smaller gauge than present in FIG. 3A. Note that the shape of the surface 42 promotes the fitting of the conductor in a central location of the termination assembly, particularly when orientated so that gravity assists in encouraging the conductor 15 to rest in a central location along the surface 42.

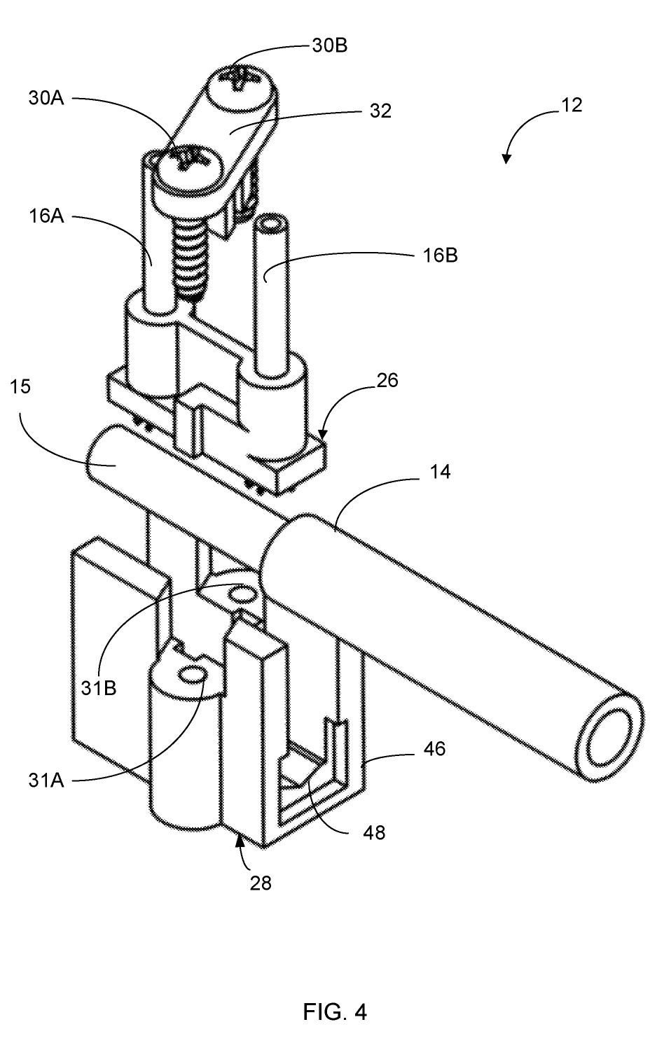

FIG. 4 is another view of the conductor position assembly 12. Note that the base assembly 28 has a generally u-shaped body 46 for holding the source conductor 14. Further at the bottom of the u-shaped body 46, the surface 48 is sloped or angled towards center to better control positioning of the source conductor 14 within the conductor position assembly 12.

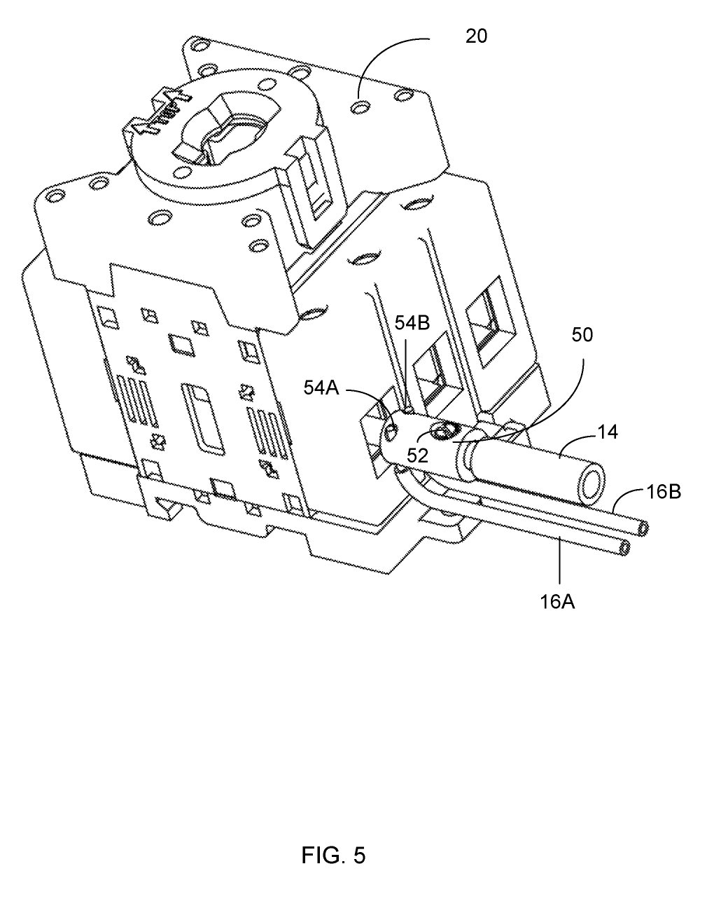

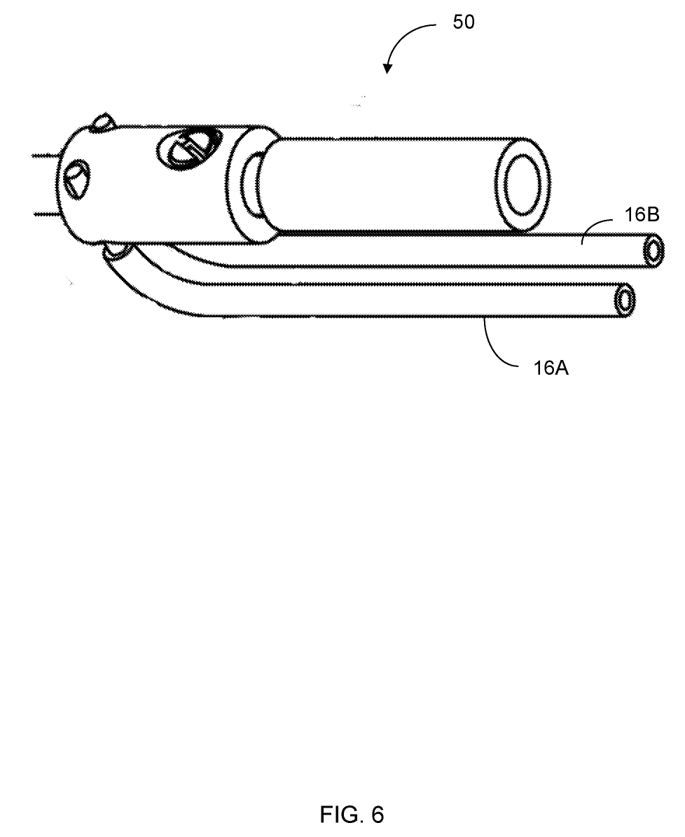

FIG. 5 illustrates another example of a conductor position assembly in the form of an in-line male-female lug 50 with dual crimp and/or screw terminations. As shown in FIG. 5, a rotary switch 20 is present. FIG. 6 further shows the lug 50. The source conductor 14 is shown. A screw 52 is used to secure the log to the source conductor. The voltage sense leads 16A, 16B may have terminations 54A, 54B secured through crimping or screw terminations. Note that the voltage sense leads 16A, 16B are spaced apart from one another to connect with the source conductor at different points.

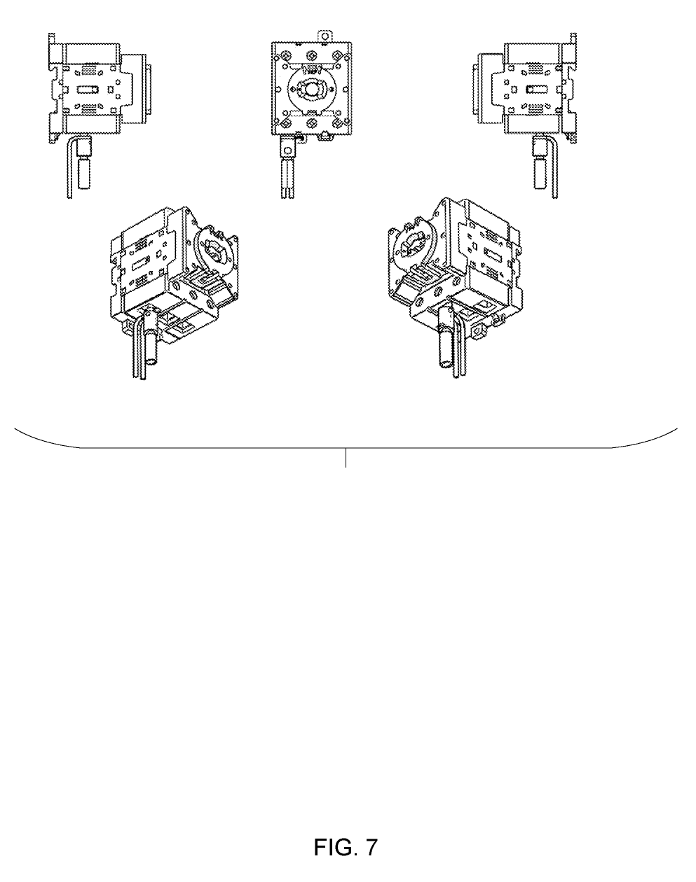

FIG. 7 further illustrates the male-female lug adapter wired to a rotary disconnect switch.

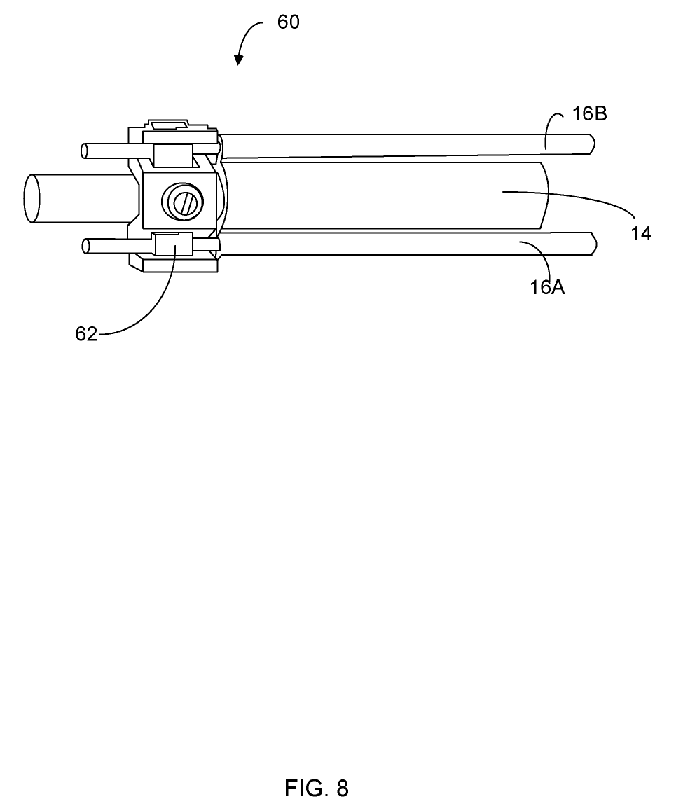

A further example of a configuration for a conductor position assembly 60 is shown in FIG. 8 in the form of a ring collar adapter 62 with two voltage sense lead screw terminations. The adapter 62 may fit over the source conductor 14 with the voltage sensor leads 16A, 16B on opposite sides of the source conductor 14 or at least in a spaced apart relationship with one another.

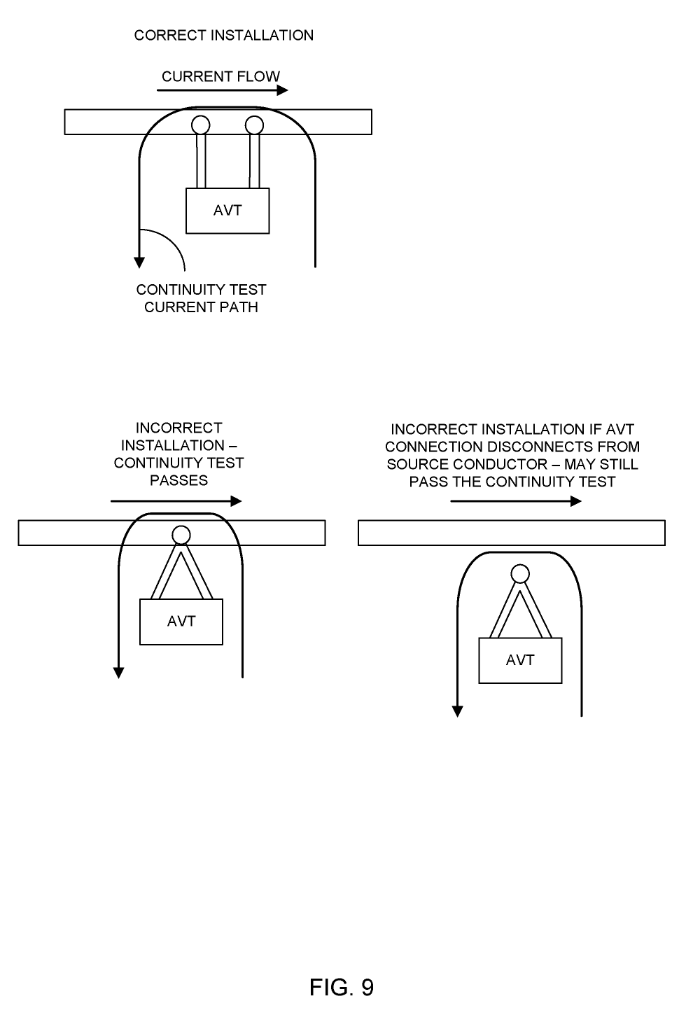

FIG. 9 illustrates the importance of the spaced apart terminations of the voltage sense leads to the source conductor in the context of an absence of voltage tester. If voltage sense lead wires are properly positioned such that both terminate at the source conductor but at separated or spaced apart locations along the conductor then current flow between the voltage sense lead wires along the source conductor allows for an accurate continuity test. However, if there is an incorrect installation and the voltage sense leads are in contact with one another without being separated along the source conductor then this installation may still result in a continuity test passing but the continuity test would not be testing current flow along the source conductor. If there is an incorrect installation and neither of the voltage sense leads associated with an AVT are terminated at the source conductor then the continuity test may pass, but is not indicative of testing current flow along the source conductor. Thus, in the context of an AVT and continuity testing the conductor position assembly is highly advantageous in properly and correctly positioning voltage sense leads so that contact with the source conductor is made and so that the voltage sense leads are spaced apart from one another to ensure current flow through the source conductor.

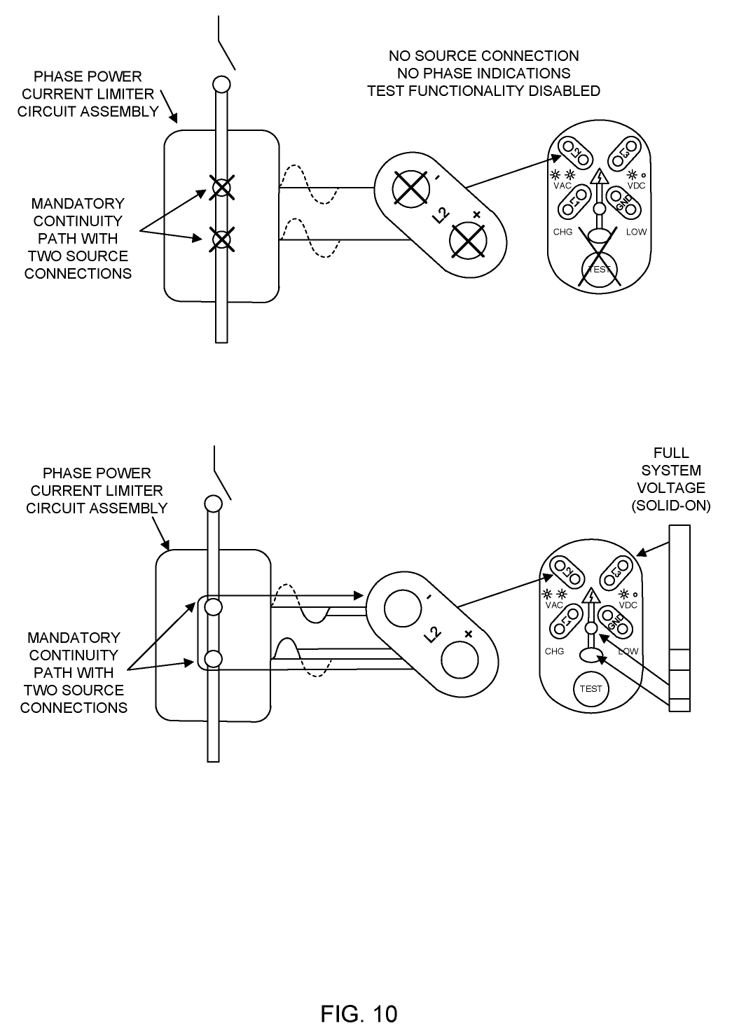

FIG. 10 further indicates how in a device such as an AVT, it is advantageous to have a mandatory continuity path with two source connections. Without a continuity path with two source connections, test functionality for the AVT would be disabled. Where when such a path is present phase indications and test functionality may be provided.

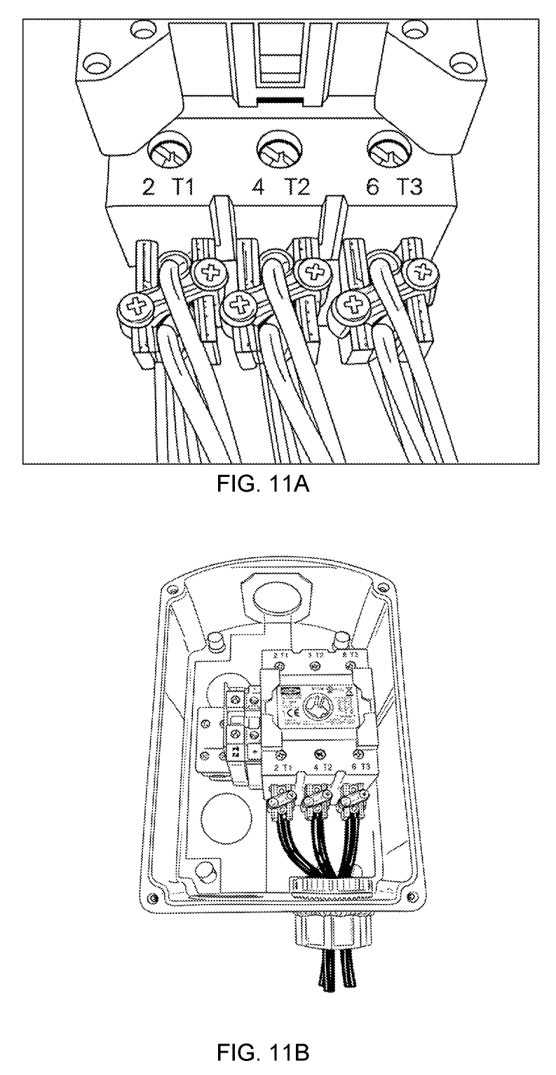

FIGS. 11A and 11B further provide illustrations of the connector-less apparatus similar to that shown in FIG. 1. Note that where used with AVT lead wire installation, there are at least three considerations. For example, new panel designs with AVTs would provide the eight voltage sense lead wires termination points. Stand-alone isolation devices and main circuit protectors, such as safety switches, motor-disconnect switches, fusible/non-fusible/visible-blade/rotary disconnect switches, and circuit breakers, are all designed to accept a range of outgoing load conductor wire sizes and have limited options for terminating voltage sensing leads without adding other hardware. In a third installation consideration, field AVT installations on higher current applications do not allow an installer to loosen the main current-carrying conductor, so the voltage sense leads must be terminated elsewhere in the control enclosure. Locating suitable termination points or drilling and tapping new points can be costly and error-prone. The voltage sense apparatus deployed in this application can save 1-2 hours in installation and ensure correct installation which are both highly advantageous.

It should also be understood that because the sensing terminations carry only the low current required for voltage measurement rather than load current, the connections are not subject to resistive heating, allowing a connector-less termination directly onto the source conductor without the thermal-cycling or failure modes associated with power-carrying connections. Electrical safety depends on highly reliable voltage-sensing connections to the source voltage.

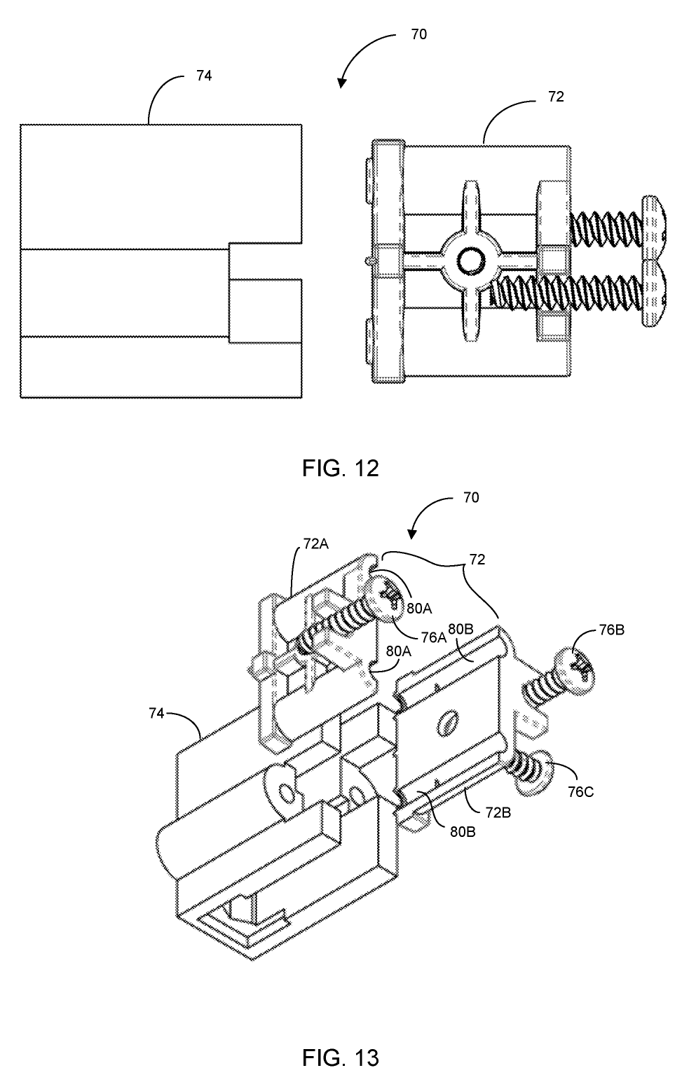

Referring now to FIGS. 12–18, another embodiment of a conductor position assembly is shown in the form of a field-installable conductor position assembly.

As shown in FIG. 12, the field-installable conductor position assembly 70 includes a termination assembly 72 and a mounting base 74. When the conductor position assembly shown is used, it may be installed in the field using a screw or other fastener to secure the wire clam shell. Thus, the conductor position assembly may connect two separate voltage sensor leads in the field using screws.

As shown in FIG. 13, the termination assembly 72 has a clamshell design comprising a first clamp body 72A and a second clamp body 72B. The first clamp body 72A and second clamp body 72B together form a clamshell-type assembly. Each clamp body 72A, 72B defines a portion 80A, 80B of wire receiving channel for receiving a respective voltage sense lead such that when the two clamp bodies are brought together, the voltage sense leads (not shown) may be held therebetween.

The field-installable conductor position assembly 70 may be secured using a first screw 76A that passes through the first clamp body 72A and presses a first voltage sense lead against the source conductor at a first location along the source conductor and into the mounting base 74. A second screw 76B passes through the second clamp body 72B and presses a second voltage sense lead against the source conductor at a second location along the source conductor and into the mounting base 74. The first location and the second location are spaced apart from one another along the source conductor so that the two voltage sense leads make electrical contact with the source conductor at two distinct, separated points. A third screw 76C secures the first clamp body 72A to the second clamp body 72B, holding the clamshell termination assembly 72 together as a unit.

The mounting base 74 includes a conductor receiving channel for receiving and positioning the source conductor. The conductor receiving channel may have a shape that accommodates a range of conductor sizes.

FIG. 13 illustrates the field-installable conductor position assembly 70 showing the termination assembly 72 and the mounting base 74 which may be the first screw 76A passing through the first clamp body 72A and the second screw 76B passing through the second clamp body 72B.

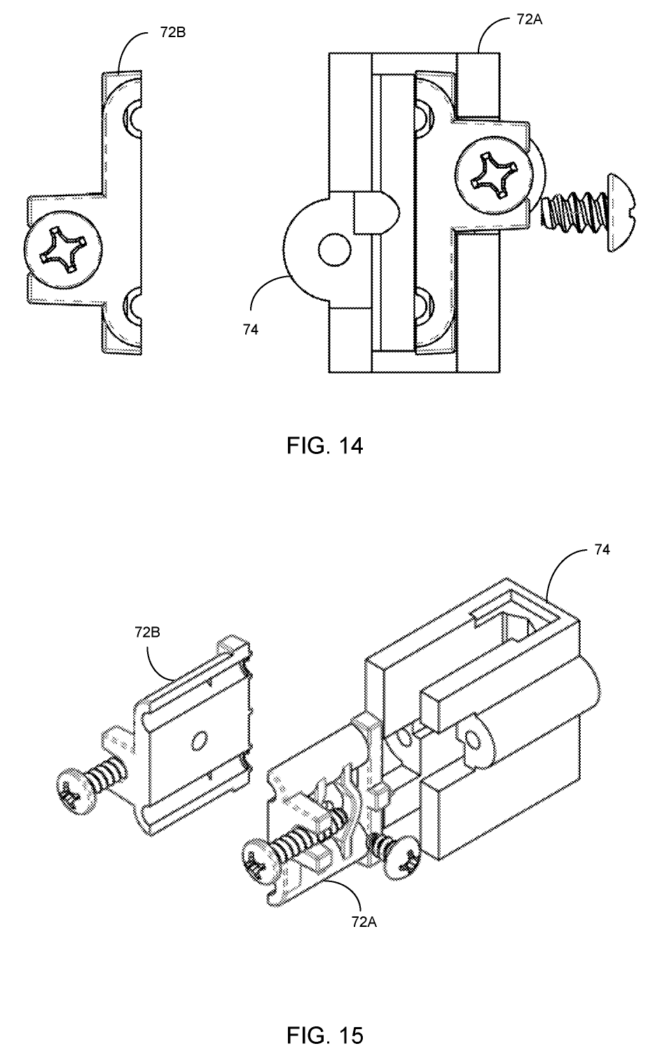

FIG. 14 illustrates another view of the clamshell termination assembly showing the first clamp body 72A and the second clamp body 72B with associated screw positions.

FIG. 15 illustrates another view of an example of the field-installable conductor position assembly with the termination assembly 72 with a first clamp body 72A, second clamp body 72B, and mounting base separated to show the individual components and the wire receiving channels for positioning the voltage sense leads.

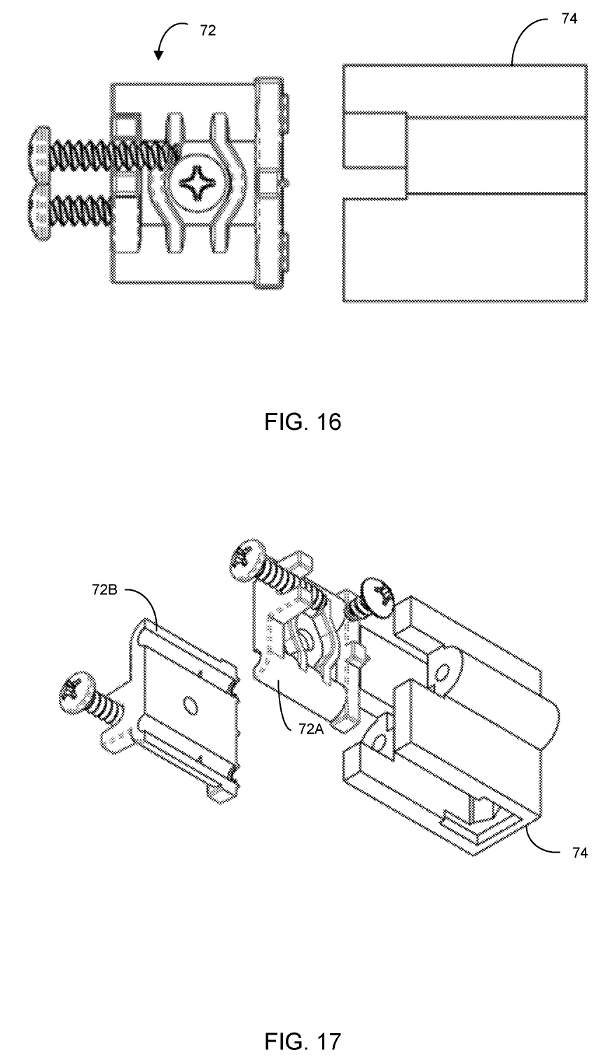

FIG. 16 illustrates a front view of the termination assembly 72 showing the first clamp body and the second clamp body assembled with the screws passing through respective clamp bodies, alongside the mounting base 74.

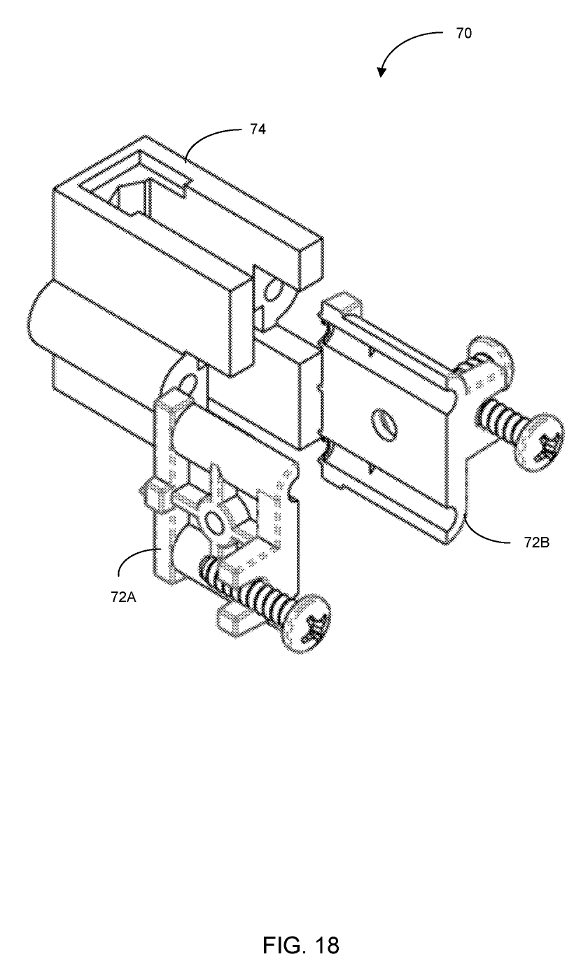

FIG. 17 illustrates another view of the field-installable conductor position assembly from an alternate angle showing the first clamp body 72A, second clamp body 72B, and mounting base 74 with their securing screws.

FIG. 18 illustrates another view of the field-installable conductor position assembly 70 showing the first clamp body 72A and second clamp body 72B mounted on the mounting base 74.

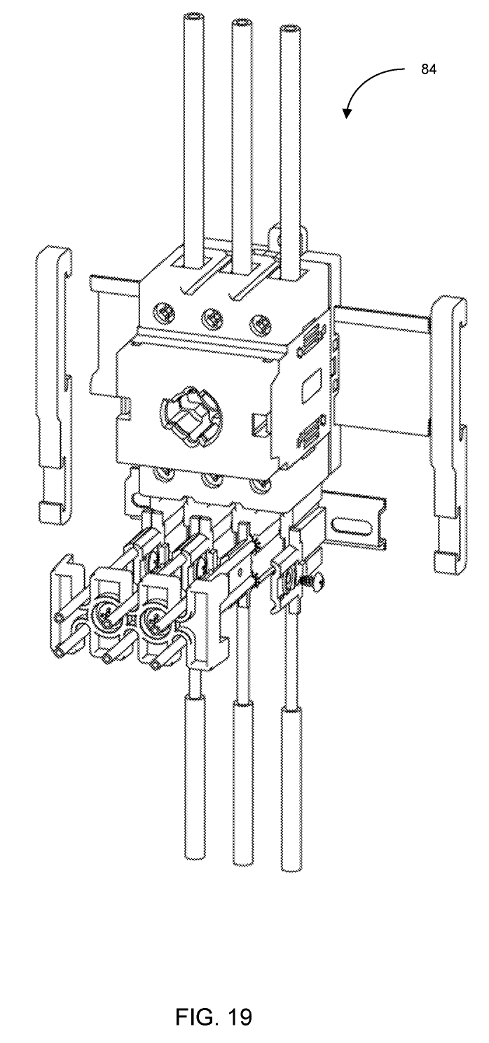

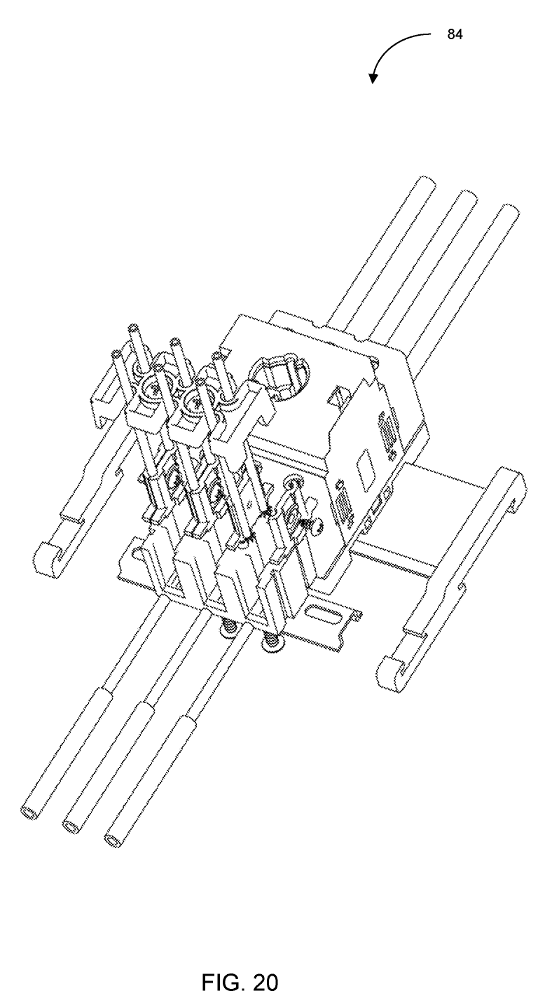

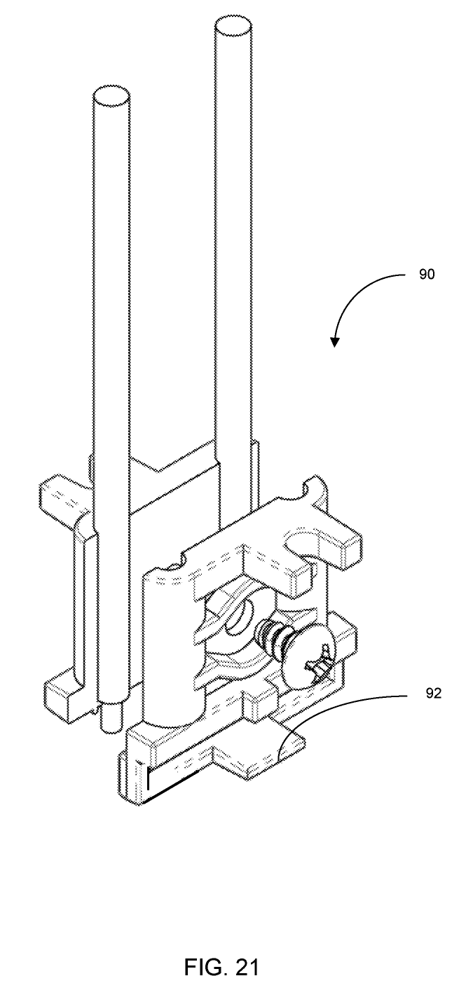

FIG. 19 illustrates one embodiment of a disconnect 84 which may mount in an enclosure assembly with a connector-less connector (or conductor position assembly) mounted in a stationary position. Once the installer pulls the conductors into the enclosure, the installer may then strip back the three conductors an extra distance such as approximately ¾ inch and insert them into the load side of a 30 amp or higher disconnect. Next, the installer can secure the conductors into the disconnect. Finally, the installer may tighten the two screws on the connector-less connector to make six connections. It is noted that the two ground conductors may be terminated into a separate dual connection terminal block. The disconnect 84 may be any type of isolation device configured to disconnect one or more source conductors from an upstream power source, including without limitation a safety switch, a rotary disconnect, a fusible disconnect, a non-fusible disconnect, a circuit breaker, and other electrical power isolation devices. In the illustrated embodiment, the disconnect 84 is depicted as a rotary disconnect. FIG. 20 illustrate another view of the device shown in FIG. 19 for a three in one device.

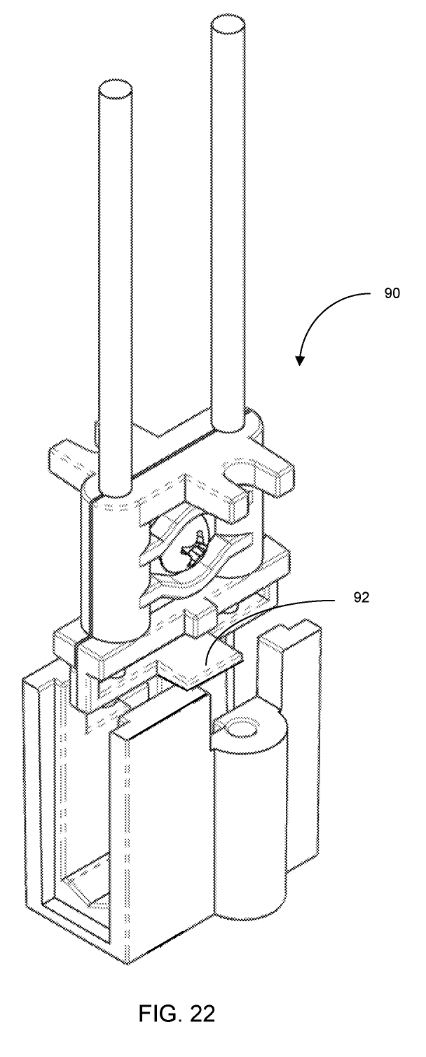

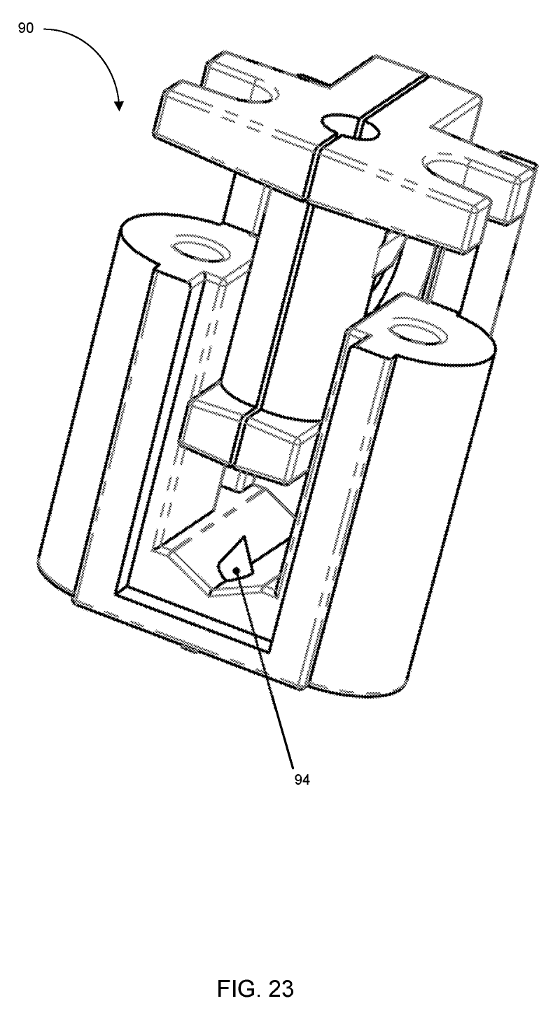

The connector-less apparatus disclosed herein is not limited to any single conductor count and may be embodied as a single-conductor (one-wire) apparatus, as a three-wire apparatus servicing the L1, L2, and L3 source conductors, or as a four-wire apparatus servicing L1, L2, L3, and an associated ground (GRD) conductor. The single-conductor embodiment is illustrated, for example, in FIGS. 22 and 23, and is suitable for applications in which only a single line voltage is sensed or in which each source conductor is serviced by an independent connector-less apparatus. The multi-conductor embodiment shown in FIGS. 19 and 20 is a three-in-one configuration in which the L1, L2, and L3 connector-less connectors share a common body and are drawn together by two screws that draw the conductor-position assembly to make six voltage-sense connections (two per source conductor). The multi-conductor configurations may be constructed in two general forms: a unitary assembly in which the connector-less connectors for each source conductor are integrated into a single meshed body sharing common structural elements and a shared mounting base, as shown in FIGS. 19 and 20, or a ganged assembly in which two, three, or four single-conductor connector-less apparatus of the type shown in FIGS. 22 and 23 are mechanically ganged side-by-side (for example, by a shared mounting base or DIN-rail carrier), each single-conductor apparatus being secured to its respective source conductor independently of the others. A four-wire variant, whether unitary or ganged, incorporates a fourth connector-less apparatus dedicated to the ground conductor, obviating the separate dual-connection ground terminal block otherwise described herein; alternatively, the ground conductors may be terminated in a separate dual-connection terminal block adjacent to a three-wire apparatus. Selection among the one-, three-, and four-wire embodiments, and between unitary and ganged multi-conductor construction, is a matter of installation requirements, available panel space, and other appropriate considerations. In three-phase wye installations in which a neutral conductor is present, a four-wire variant may alternatively incorporate a fourth connector-less apparatus dedicated to the neutral (N) conductor in place of, or in addition to, the ground conductor; a five-wire variant incorporates a fourth connector-less apparatus dedicated to the neutral conductor and a fifth connector-less apparatus dedicated to the ground conductor.

The configuration shown in FIGS. 19 and 20 is particularly advantageous for field installations where the installer needs a practical, low-cost method of terminating voltage sense leads without loosening previously torqued conductor connections or adding additional terminal blocks. The connector-less connectors may be of any of the types described herein.

FIG. 21 illustrates a sacrificial stripped-conductor position mechanism 90 including a sacrificial position tab 92. FIG. 22 illustrates another embodiment of a sacrificial stripped-conductor position mechanism 90, likewise including sacrificial position tab 92. Where the stripped wire is maintained at a uniform length which is not too long, the wire ends may be stiff and make for a better condition. For example, when 14AWG wire is used and the stripped portion is exactly at 1/8” and no longer, the wire ends are like stiff brush bristles and will dig into the load conductors and make a better connection. For 14AWG wire, there are typically 22 to 30 strands. For field installations, the wire holder mechanism may include a strip length gauge. Once the installer strips the conductor back to the correct length and inserts it into the wire holder sandwich assembly, the sacrificial position tab 92 helps ensure that the stripped 14AWG lead wire only protrudes 1/8”. Before the wire holder sandwich assembly is inserted into the other part of the assembly, the sacrificial position tab 92 or sacrificial positioned stop needs to break off. The presence of stiff brush bristles also assists in avoiding rotation.

FIG. 23 illustrates a single-conductor connector-less connector 90 configured to resist rotation in this embodiment using an anti-rotation cleat or spike 94 positioned to resist rotation. FIG. 23 may also illustrate the pieces put together after removal of sacrificial position tab. A single-conductor connector-less connector may rotate. A user may perceive that this rotation is indicative of other issues such as that the device is flimsy or not sufficiently robust. One way to address this, as shown here, is by configuring the device to resist rotation. As shown here, additional structure for resisting rotation is added in the form of the anti-rotation cleat or spike 94. This issue may also be addressed in alternative ways. For example, material such as rubberized material or other material with a gripping surface may be used to grab onto or grip the conductor to prevent or resist rotation. Another example of anti-rotation structure may include a rubber bumper positioned to resist rotation.

While several embodiments of the connector-less apparatus have been described, it should be understood that the present invention is not limited to these specific embodiments. Various modifications and alternatives may be implemented without departing from the scope of the invention.

For example, the described embodiments may be used for three-phase power conductors (L1, L2, L3), the connector-less apparatus may also be configured for single-phase applications, two-phase applications, or other multi-phase power systems. Similarly, the apparatus could be adapted for DC power applications where appropriate.

The materials used for construction of the apparatus may vary. While insulative overmolding with rubber-like material is described for certain embodiments, alternative insulative materials such as engineered thermoplastics, silicone compounds, or other dielectric materials with suitable mechanical properties could be employed. The conductive components may be constructed from various metals or metal alloys selected for optimal conductivity, corrosion resistance, and mechanical durability.

In some embodiments, a field installable “termination end” may be used which will snap or screw around the VSLs instead of the overmolded embodiments. Any number of different manufacturing techniques may be employed. For example, the field installable termination end may be an injection molded two-part assembly that uses a fastener such as a screw or is configured to snap-together to secure, sandwich, clamp, and position the lead-wires in the correct location with a sufficient amount of “meshing” length on the stripped wire. One application of such an environment is for use with a PESD. In operation, an installer may strip the wire to a pre-determined length and the 2-part assembly may then attach together such as by snapping or screw or other fastener and then may be inserted into the conduction positioning assembly as previously described.

The physical configuration of the apparatus may be modified to accommodate specific installation environments or equipment types. For instance, the apparatus could be designed with alternative mounting options such as DIN rail mounting, panel mounting, or direct attachment to existing electrical hardware. The spacing between voltage sense lead terminations could be adjusted based on the specific requirements of the continuity testing circuit while maintaining the critical separation needed for proper operation.

While the embodiments describe accommodating various wire gauges from #14AWG to 500MCM, the apparatus could be scaled for even smaller or larger conductors as needed for specific applications. Additionally, the clamping mechanism could be modified to incorporate alternative fastening technologies such as spring-loaded clamps, quick-disconnect systems, or tool-free designs to further reduce installation time.

The apparatus may also be integrated with additional safety or monitoring features. For example, visual indicators such as LEDs could be incorporated to provide status information about the connections. The apparatus could also be designed to work with wireless monitoring systems that transmit status information to remote locations.

Furthermore, while the apparatus is primarily described for use with AVTs, this is not limiting, as the dual-point connection methodology could be applied to other electrical safety systems, power monitoring devices, or electrical test equipment where reliable connections to current-carrying conductors are required.

As used herein, the term "connector-less" refers to an apparatus or method of establishing electrical contact between a voltage sense lead wire and a source conductor through direct mechanical contact, such as by pressing, mashing, or clamping, without requiring a traditional electrical connector, terminal, lug, or solderless crimp terminal at the point of connection to the source conductor.

As used herein, the term "voltage sense lead" or "VSL" refers to a lead wire such as used by an electrical safety device to sense voltage or to perform continuity testing on a source conductor, including but not limited to lead wires used by absence of voltage testers (AVTs), permanent electrical safety devices (PESDs), and other power monitoring devices.

As used herein, the term "source conductor" refers to a current-carrying conductor in an electrical power system, including but not limited to phase conductors (L1, L2, L3) and ground conductors in single-phase, two-phase, three-phase, or other multi-phase electrical systems, as well as conductors in DC power systems.

As used herein, the term "conductor position assembly" refers to any assembly configured to hold a source conductor and to mechanically and electrically connect one or more voltage sense leads to the source conductor, including but not limited to overmolded assemblies, clamshell assemblies, lug adapters, ring collar adapters, and single-conductor connector assemblies.

As used herein, the term "spaced apart" in the context of voltage sense lead positions along a source conductor means that the two positions are sufficiently separated along the length of the source conductor such that test current injected through one voltage sense lead flows along the source conductor between the two positions before returning through the other voltage sense lead, rather than flowing directly between the two voltage sense leads without traversing a meaningful length of the source conductor.

As used herein, the term "mashed end" refers to a stripped end of a stranded wire that has been flattened, spread, or otherwise deformed to increase the number of individual wire strands that contact the surface of the source conductor, thereby creating multiple redundant electrical contact paths.

As used herein, the term "electrical safety device" includes but is not limited to absence of voltage testers (AVTs), permanent electrical safety devices (PESDs), voltage indicators, power monitoring devices, and other devices used to verify the presence or absence of electrical energy on conductors or circuit parts.

As used herein, the singular forms "a," "an," and "the" include plural referents unless the context clearly dictates otherwise.

As used herein, the term "or" is inclusive, meaning "and/or" unless the context clearly indicates otherwise.

As used herein, the terms "comprises," "comprising," "includes," "including," "has," "having," or any other variation thereof are intended to cover non-exclusive inclusions.

These and other variations, modifications, and alternatives will be apparent to those skilled in the art in view of the foregoing description. Accordingly, this description is to be construed as illustrative only and is for the purpose of teaching those skilled in the art the best mode of carrying out the invention.

What is claimed is:

1. A connector-less apparatus for electrical safety devices, comprising:
a first termination for a first voltage sense lead;
a second termination for a second voltage sense lead;
an opening for receiving a source conductor; and
wherein the apparatus is configured such that the first voltage sense lead wire contacts the source conductor at a first position along the source conductor and the second voltage sense lead wire contacts the source conductor at a second position along the source conductor, the first position spaced apart from the second position such that current flows along the source conductor between the first voltage sense lead and the second voltage sense lead when electrical energy is present on the source conductor.

2. An apparatus comprising a plurality of the connector-less apparatus for electrical safety devices of claim 1 with a first connector-less apparatus for a L1 source conductor, a second connector-less apparatus for a L2 source conductor, a third connector-less apparatus for a L3 source conductor.

3. The apparatus of claim 2 wherein the first connector-less apparatus, the second connector-less apparatus, and the third connector-less apparatus are mechanically ganged side-by-side, each being secured to its respective source conductor independently of the others.

4. The apparatus of claim 2 wherein the first connector-less apparatus, the second connector-less apparatus, and the third connector-less apparatus are integrated into a unitary body sharing common structural elements and a shared mounting base.

5. The connector-less apparatus for electrical safety devices of claim 1 wherein the opening is between a first assembly and a base assembly.

6. The connector-less apparatus for electrical safety devices of claim 5 wherein the first assembly is configured to receive the first voltage sense lead and the second voltage sense lead.

7. The connector-less apparatus for electrical safety devices of claim 6 wherein the first assembly provides an overmolded termination end for receiving both the first voltage sense lead and the second voltage sense lead configured such that in an operative position both the first voltage sense lead and the second voltage sense lead electrically connect to the source conductor.

8. The connector-less apparatus for electrical safety devices of claim 1 further comprising a two-part body which secures around the voltage sense leads.

9. The connector-less apparatus of claim 8 is operatively connected to a permanent electrical safety device.

10. The connector-less apparatus of claim 1, wherein at least one surface defining a portion of the opening has a contoured shape configured to center the source conductor within the opening across a range of conductor gauge sizes.

11. The connector-less apparatus of claim 1, further comprising a sacrificial position tab associated with at least one of the first termination and the second termination, the sacrificial position tab configured to gauge a stripped length of the corresponding voltage sense lead wire and configured to be removed prior to the apparatus reaching an operative position.

12. The connector-less apparatus of claim 1, further comprising anti-rotation structure configured to resist rotation of the apparatus relative to the source conductor.

13. A connector-less apparatus for electrical safety devices, comprising:
an L1 source conductor sub-assembly comprising:
a first termination for a first voltage sense lead wire;
a second termination for a second voltage sense lead wire;
an opening for receiving an L1 source conductor;
wherein the apparatus is configured such that the first voltage sense lead wire contacts the L1 source conductor at a first position along the L1 source conductor and the second voltage sense lead wire contacts the L1 source conductor at a second position along the L1 source conductor, the first position spaced apart from the second position such that current flows along the L1 source conductor between the first voltage sense lead and the second voltage sense lead when electrical energy is present on the L1 source conductor;
an L2 source conductor sub-assembly comprising:
a first termination for a first voltage sense lead wire;
a second termination for a second voltage sense lead wire;
an opening for receiving an L2 source conductor;
wherein the apparatus is configured such that the first voltage sense lead wire contacts the L2 source conductor at a first position along the L2 source conductor and the second voltage sense lead wire contacts the L2 source conductor at a second position along the L2 source conductor, the first position spaced apart from the second position such that current flows along the L2 source conductor between the first voltage sense lead and the second voltage sense lead when electrical energy is present on the L2 source conductor;
an L3 source conductor sub-assembly comprising:
a first termination for a first voltage sense lead wire;
a second termination for a second voltage sense lead wire;
an opening for receiving an L3 source conductor; and
wherein the apparatus is configured such that the first voltage sense lead wire contacts the L3 source conductor at a first position along the L3 source conductor and the second voltage sense lead wire contacts the L3 source conductor at a second position along the L3 source conductor, the first position spaced apart from the second position such that current flows along the L3 source conductor between the first voltage sense lead and the second voltage sense lead when electrical energy is present on the L3 source conductor.

14. The connector-less apparatus of claim 13 further comprising:
a ground conductor sub-assembly comprising:
a first termination for a first voltage sense lead wire;
a second termination for a second voltage sense lead wire;
an opening for receiving a ground conductor;
wherein the apparatus is configured such that the first voltage sense lead wire contacts the ground conductor at a first position along the ground conductor and the second voltage sense lead wire contacts the ground conductor at a second position along the ground conductor, the first position spaced apart from the second position such that current flows along the ground conductor between the first voltage sense lead and the second voltage sense lead when electrical energy is present on the ground conductor.

15. The connector-less apparatus of claim 13 further comprising an isolation device configured to disconnect the L1, L2, and L3 source conductors from an upstream power source, wherein the isolation device comprises one of a safety switch, a rotary disconnect, a fusible disconnect, a non-fusible disconnect, and a circuit breaker.

16. A connector-less apparatus for electrical safety devices, comprising:
a two-part assembly configured to receive a first voltage sense lead and a second voltage sense lead, the two-part assembly configured to hold the first voltage sense lead and the second voltage sense lead such that a stripped end of the first voltage sense lead and a stripped end of the second voltage sense lead protrude from the two-part assembly; and
a base assembly configured to hold a first source conductor;
wherein the two-part assembly is configured to be inserted into and secured to the base assembly such that, in an operative position, the stripped end of the first voltage sense lead meshes against the first source conductor at a first position along the first source conductor and the stripped end of the second voltage sense lead meshes against the first source conductor at a second position along the first source conductor spaced apart from the first position, such that current flows along the first source conductor between the first voltage sense lead and the second voltage sense lead when electrical energy is present on the first source conductor.

17. The connector-less apparatus of claim 16, wherein the two-part assembly comprises a first clamp member and a second clamp member configured to mate together, the first clamp member and the second clamp member together defining a first wire channel configured to receive the first voltage sense lead and a second wire channel configured to receive the second voltage sense lead.

18. The connector-less apparatus of claim 17, further comprising a first fastener passing through the first clamp member and into the base assembly, and a second fastener passing through the second clamp member and into the base assembly, the first fastener and the second fastener configured to secure the two-part assembly to the base assembly in the operative position.

19. The connector-less apparatus of claim 18, further comprising a third fastener securing the first clamp member to the second clamp member.

20. The connector-less apparatus of claim 17, further comprising a sacrificial position tab associated with the two-part assembly, the sacrificial position tab configured to gauge a stripped length of at least one of the first voltage sense lead and the second voltage sense lead and configured to be removed prior to the two-part assembly being inserted into the base assembly.

21. The connector-less apparatus of claim 16 further comprising an anti-rotation structure positioned on the base assembly and configured to engage the first source conductor to resist rotation of the apparatus relative to the source conductor, wherein the anti-rotation structure comprises at least one of a cleat, a spike, and a gripping surface configured to engage the first source conductor.
